(19) United States
(12) Patent Application Publication
(10) Pub. No.: US 2010/0001265 A1
(43) Pub. Date: Jan. 7, 2010

(54) Thin film transistor, method of fabricating the same, and organic light emitting diode display device including the same

(76) Inventors: Ji-Su Ahn, Yongin City (KR); Sung-Chul Kim, Yongin City (KR)

Correspondence Address: LEE & MORSE, P.C., 3141 FAIRVIEW PARK DRIVE, SUITE 500, FALLS CHURCH, VA, 22042, US

(21) Appl. No.: 12/458,125

(22) Filed: Jul. 1, 2009

(30) Foreign Application Priority Data
Jul. 2, 2008 (KR) 10-2008-0064002

(51) Int. Cl. H01L 51/52; H01L 29/786; H01L 21/336

(52) U.S. Cl. 257/40; 257/66; 438/166; 257/E29.273; 257/E51.022; 257/E21.412

(57) ABSTRACT

The thin film transistor for an organic light emitting diode includes a crystalline semiconductor pattern on a substrate, a gate insulating layer on the crystalline semiconductor pattern having first source and drain contact holes, a gate electrode on the gate insulating layer, the gate electrode being between the first source and drain contact holes, an interlayer insulating layer covering the gate electrode, having second source and drain contact holes, source and drain electrode in the second source and drain contact holes, insulated from the gate electrode and electrically connected to the crystalline semiconductor pattern by first and second metal patterns in the first source and drain contact holes, respectively, wherein the gate electrode, the first metal pattern in the first source contact hole and the second metal pattern in the first drain contact hole are each made of a same material.

### BACKGROUND OF THE INVENTION

1. Field of the Invention

Embodiments relate to a thin film transistor, a method of fabricating the same, and an organic light emitting diode display device including the same. More particularly, embodiments relate to a thin film transistor (TFT) that can prevent generated Joule heat from generating an arc during a conventional crystallization process.

2. Description of the Related Art

Annealing methods used during a crystallization process generally include a furnace annealing method using a heat furnace, a rapid thermal annealing (RTA) method using radiant heat, e.g., a halogen lamp, a laser annealing method using a laser, and an annealing method using Joule heating. Among available annealing methods, an appropriate annealing method for the crystallization process is determined based on characteristics of material and process contemplated. Some of the factors to be considered in the selection of an appropriate annealing method are a range of an annealing temperature, uniformity of the annealing temperature, a heating rate, a cooling rate, purchase price, and maintenance cost. However, a selection of annealing method becomes very limited when high temperature annealing or high rate annealing only in a local region of a material is needed.

The laser annealing method can rapidly anneal a surface of a material. Despite this advantage, the laser annealing method has only limited applicability, since it can only be used to anneal particular materials. When scanned linear laser beams overlap to anneal a large-sized device, non-uniformity in intensity of the laser beam and in irradiation level of the laser beam may occur. Also, the laser annealing method requires very expensive equipment, as well as incurring high maintenance cost.

The RTA method is widely applied to a semiconductor fabrication process. With current technology, however, RTA methods can be applied only to a 300 mm wafer, so it is difficult to uniformly anneal a substrate larger than 300 mm. Moreover, this method has a maximum heating rate of about 400° C./sec, and thus cannot be applied to a process requiring a higher heating rate than 400° C./sec. Thus, research has been widely conducted on annealing methods to solve these problems and to eliminate processing limitations.

### SUMMARY OF THE INVENTION

Embodiments are therefore directed to a TFT, a method of fabricating the same, and an organic light emitting diode (OLED) display device using the same, which substantially overcome one or more of the disadvantages of the related art.

It is therefore a feature of an embodiment to provide a TFT having a semiconductor layer crystallized by application of an electrical field as the result of heat transfer from a metal layer, and configured to prevent an arc formation during the crystallization of an amorphous layer.

It is therefore another feature of an embodiment to provide a TFT having a semiconductor layer crystallized by application of an electrical field, and capable of reducing contact resistance between source and drain electrodes and the semiconductor layer.

It is therefore another feature of an embodiment to provide a method of fabricating a TFT exhibiting the above features and an OLED display device including the TFT.

At least one of the above features and other advantages may be realized by providing a thin film transistor (TFT), including a crystalline semiconductor pattern on a substrate, a gate insulating layer on the crystalline semiconductor pattern, the gate insulating layer having a first source contact hole and a first drain contact hole therein, a gate electrode on the gate insulating layer, the gate electrode being between the first source contact hole and the first drain contact hole, an interlayer insulating layer covering the gate electrode, the interlayer insulating layer having a second source contact hole and a second drain contact hole therein, a source electrode in the second source contact hole, the source electrode insulated from the gate electrode and electrically connected to the crystalline semiconductor pattern by a first metal pattern in the first source contact hole, and a drain electrode in the second drain contact hole, the drain electrode insulated from the gate electrode and electrically connected to the crystalline semiconductor pattern by a second metal pattern in the first drain contact hole. The gate electrode, the first metal pattern in the first source contact hole, and the second metal pattern in the first drain contact hole may each be made of a same material.

The gate electrode may be formed of a single layer or multiple layers, in which, when the gate electrode is formed of a single layer, the single layer is aluminum or an aluminum alloy, and, when the gate electrode is formed of multiple layers, the multiple layers include a first layer of an aluminum alloy and a second layer of a chromium or molybdenum alloy.

The first and second metal patterns may each be formed of a single layer or multiple layers, in which, when the first and second metal patterns are formed of a single layer, the single layer is aluminum or an aluminum alloy, and, when the first and second metal patterns are formed of multiple layers, the multiple layers include a first layer of an aluminum alloy and a second layer of a chromium or molybdenum alloy.

The TFT may further include a buffer layer between the substrate and the crystalline semiconductor pattern.

At least one of the above features and other advantages may be realized by providing a method of fabricating a thin film transistor, the method including forming an amorphous semiconductor layer on a substrate, patterning the amorphous semiconductor layer to form an amorphous semiconductor pattern, forming a gate insulating layer on the amorphous semiconductor pattern, forming a first source contact hole and a first drain contact hole in the gate insulating layer, forming a metal layer on the substrate, the metal layer covering the gate insulating layer, and being in the first source contact hole and the first drain contact hole so as to be electrically connected therethrough to the amorphous semiconductor pattern, passing an electric current through the metal layer so as to convert the amorphous semiconductor pattern to a crystallized semiconductor pattern using heat generated by the electric current, patterning the metal layer to form a gate electrode corresponding to the crystallized semiconductor pattern, a first metal pattern in the first source contact hole, and a second metal pattern in the first drain contact hole, forming an interlayer insulating layer on the gate electrode, the first metal pattern, and the second metal pattern, forming a second source contact hole and a second drain contact hole in the interlayer insulating layer, and forming source and drain electrodes electrically connected to the first and second metal patterns, respectively, through the second source contact hole and the second drain contact hole.

The electric current may be generated by applying an electrical field of about 100 V/cm² to about 10,000 V/cm² to the metal layer.

A same mask may be used to form the first source contact hole, the first drain contact hole, the second source contact hole, and the second drain contact hole.

The metal layer may be formed of a single layer or multiple layers, in which, when the metal layer is formed of a single layer, the single layer is aluminum or an aluminum alloy, and, when the metal layer is formed of multiple layers, the multiple layers include a first layer of an aluminum alloy and a second layer of a chromium or molybdenum alloy.

The metal layer may be formed to a thickness of about 50 nm to about 200 nm.

The method may further include forming a buffer layer on the substrate before forming the amorphous semiconductor layer, such that the buffer layer is between the amorphous semiconductor layer and the substrate.

At least one of the above features and other advantages may be realized by providing an organic light emitting diode (OLED) display device, including OLEDs configured to emit light, and thin film transistors (TFTs) coupled to the OLEDs, each TFT including a crystalline semiconductor pattern on a substrate, a gate insulating layer on the crystalline semiconductor pattern, the gate insulating layer having a first source contact hole and a first drain contact hole therein, a gate electrode on the gate insulating layer, the gate electrode being between the first source contact hole and the first drain contact hole, an interlayer insulating layer covering the gate electrode, the interlayer insulating layer having a second source contact hole and a second drain contact hole therein, a source electrode in the second source contact hole, the source electrode insulated from the gate electrode and electrically connected to the crystalline semiconductor pattern by a first metal pattern in the first source contact hole, and a drain electrode in the second drain contact hole, the drain electrode insulated from the gate electrode and electrically connected to the crystalline semiconductor pattern by a second metal pattern in the first drain contact hole. The gate electrode, the first metal pattern in the first source contact hole, and the second metal pattern in the first drain contact hole may each be made of a same material.

The gate electrode may be formed of a single layer or multiple layers, in which, when the gate electrode is formed of a single layer, the single layer is aluminum or an aluminum alloy, and, when the gate electrode is formed of multiple layers, the multiple layers include a first layer of an aluminum alloy and a second layer of a chromium or molybdenum alloy.

The first and second metal patterns may be each formed of a single layer or multiple layers, in which, when the first and second metal patterns are formed of a single layer, the single layer is aluminum or an aluminum alloy, and, when the first and second metal patterns are formed of multiple layers, the multiple layers include a first layer of an aluminum alloy and a second layer of a chromium or molybdenum alloy.

The OLED display device may further include a buffer layer between the substrate and the crystalline semiconductor pattern.

### BRIEF DESCRIPTION OF THE DRAWINGS

The above and other features and advantages will become more apparent to those of ordinary skill in the art by describing in detail example embodiments with reference to the attached drawings, in which:

FIGS. 1A to 1D illustrate cross-sectional views of stages in a method of making a TFT according to a first example embodiment; and

FIG. 2 illustrates a cross-sectional view of an OLED display device according to a second example embodiment.

### DETAILED DESCRIPTION OF THE INVENTION

Korean Patent Application No. 10-2008-0064002, filed on Jul. 2, 2008, in the Korean Intellectual Property Office, and entitled: “Thin Film Transistor, Method of Fabricating the Same, and Organic Light Emitting Diode Display Device Including the Same,” is incorporated by reference herein in its entirety.

Embodiments will now be described more fully hereinafter with reference to the accompanying drawings, however, may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of.” For example, the expression “at least one of A, B, and C” may also include an nth member, where n is greater than 3, whereas the expression “at least one selected from the group consisting of A, B, and C” does not.

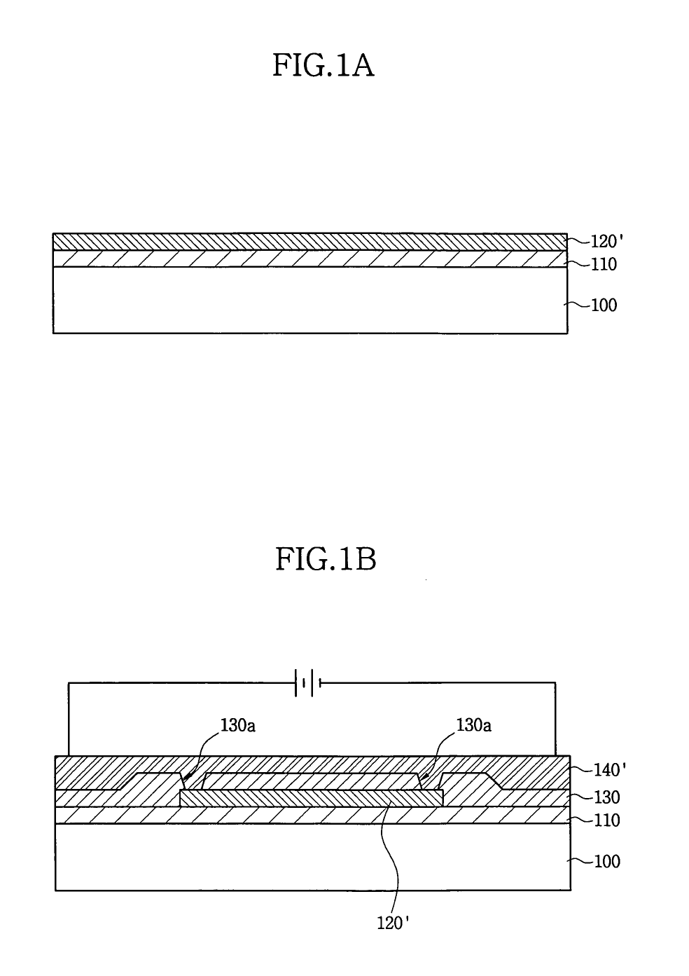

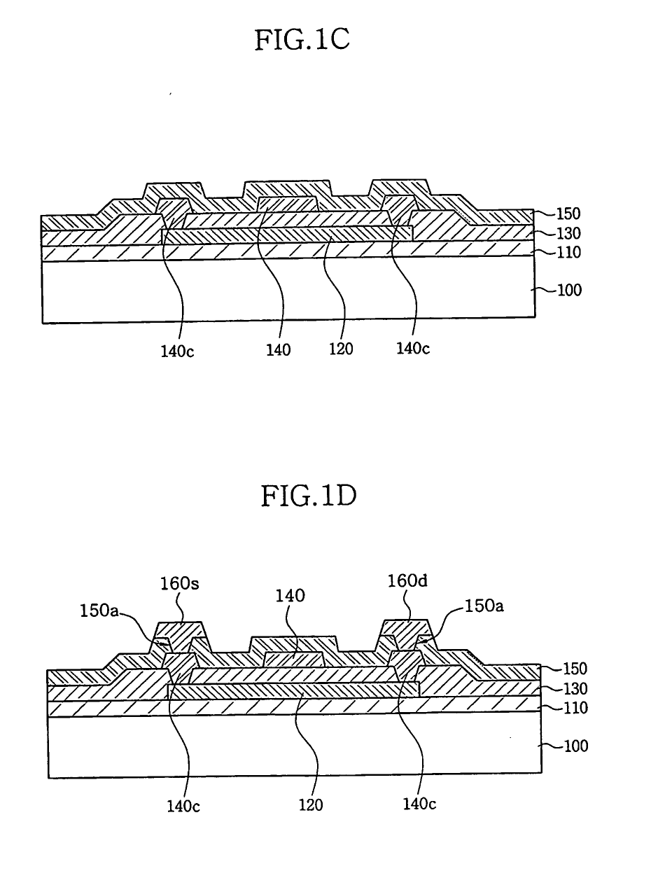

FIGS. 1A to 1D illustrate cross-sectional views of stages in a method of making a TFT according to a first example embodiment.

Referring to FIG. 1A, a substrate 100 is provided. The substrate 100 may be formed of, e.g., a transparent material such as glass or plastic. A buffer layer 110 may be on the substrate 100. The buffer layer 110 may prevent or reduce out-diffusion of moisture or impurities from the substrate 100, and/or may control a heat transfer rate during crystallization to facilitate the crystallization of an amorphous semiconductor layer. The buffer layer 110 may be, e.g., a silicon oxide layer, a silicon nitride layer, or a combination thereof.

Subsequently, an amorphous semiconductor layer 120′, e.g., amorphous silicon, may be formed on the substrate 100. As described in additional detail below, the amorphous semiconductor layer 120′ may be patterned, after which it may be crystallized to form a crystalline semiconductor pattern 120.

Referring to FIG. 1B, a gate insulating layer 130 may be on the entire surface of the substrate 100 including the semiconductor pattern 120′. The gate insulating layer 130 may be, e.g., a silicon oxide layer, a silicon nitride layer, or a combination thereof.

A first contact hole 130a may be formed on the gate insulating layer 130 to partially expose the semiconductor pattern 120′. The first contact hole 130a may be formed using a mask from which source and drain electrodes may be formed in the later stage. First contact holes 130a may be made for both source and drain contacts.

A metal layer 140′ may be formed on the entire surface of the substrate 100. The first contact hole 130a may be filled with the metal layer 140′, thereby enabling direct contact between the metal layer 140′ and the patterned amorphous semiconductor layer (amorphous semiconductor pattern) 120′. As the result of direct contact between the metal layer 140′ and the amorphous semiconductor pattern 120′, an arc generated during the crystallization of the amorphous semiconductor pattern may be prevented.

The metal layer 140′ may be formed to a suitable thickness to be used as a gate electrode 140 (shown in FIG. 1C), e.g., about 50 nm to about 200 nm. When the thickness of the metal layer 140′ is less than about 50 nm, the gate electrode 140 may not be uniformly formed and thus, heat may not be uniformly transferred to the amorphous semiconductor pattern 120′. When the thickness of the metal layer 140′ is greater than about 200 nm, the gate electrode 140 may not be thick enough for a thin film device. The metal layer 140′ may be a single layer, e.g., aluminum (Al), an Al alloy such as aluminum-neodymium (Al—Nd), etc., or a multi layer formed by stacking, e.g., an aluminum (Al) alloy on a chromium (Cr) or molybdenum (Mo) alloy.

Referring FIG. 1B, when an electrical field is applied to the metal layer 140′, a current may flow therethrough, and heat generated by the current from Joule heating may be transferred to the amorphous semiconductor pattern 120′ to induce crystallization. As the result, the amorphous semiconductor pattern 120′ may be crystallized into a crystalline semiconductor pattern 120, e.g., a polycrystalline pattern such as polycrystalline silicon.

For preferable crystallization, a voltage of about 100 V/cm² to about 10,000 V/cm² may be applied for about 1 μs to about 1 sec to the metal layer 140′. An electrical field of less than about 100 V/cm² may not generate sufficient current for Joule heating for crystallization, while an electrical field of more than about 10,000 V/cm² may generate a local arc. Further, when the electrical field is applied for less than about 1 μs, the crystallization may not be facilitated due to insufficient Joule heat, and when the electrical field is applied for more than about 1 sec, so much heat may be generated that the substrate may be bent, or may form a defect along the edge as heat transfers during the crystallization.

Referring to FIG. 1C, after forming the crystalline semiconductor pattern 120, the metal layer 140′ may be patterned to form a gate electrode 140 corresponding to the semiconductor pattern 120.

During formation of the gate electrode 140, metal patterns 140c may remain in the first contact holes 130a. The metal patterns 140c disposed in the first contact holes 130a may reduce contact resistance between source and drain electrodes 160s and 160d (shown in FIG. 1D) and the crystalline semiconductor pattern 120 in a subsequent process.

An interlayer insulating layer 150 may be on the entire surface of the substrate 100 including the gate electrode 140. The interlayer insulating layer 150 may be, e.g., a silicon nitride layer, a silicon oxide layer, or a combination thereof.

Referring to FIG. 1D, a second contact hole 150a may be formed on the interlayer insulating layer 150 using the same mask from which the first contact hole 130a was formed. Second contact holes 150a may be made for both source and drain contacts. The second contact hole 150a may partially expose the metal pattern 140c disposed on the first contact hole 130a.

Subsequently, the source and drain electrodes 160s and 160d may be formed on the interlayer insulating layer 150 to be electrically connected to the metal patterns 140c partially exposed through the respective second contact holes 150a. Thus, the source and drain electrodes 160s and 160d may be in direct contact with the metal patterns 140c, and may be electrically connected to the crystalline semiconductor pattern 120. The source and drain electrodes 160s and 160d may be formed of one or more of molybdenum (Mo), chromium (Cr), tungsten (W), MoW, aluminum (Al), Al—Nd, titanium (Ti), titanium nitride (TiN), copper (Cu), a Mo alloy, an Al alloy, and a Cu alloy. Accordingly, the TFT according to the first example embodiment may be completed.

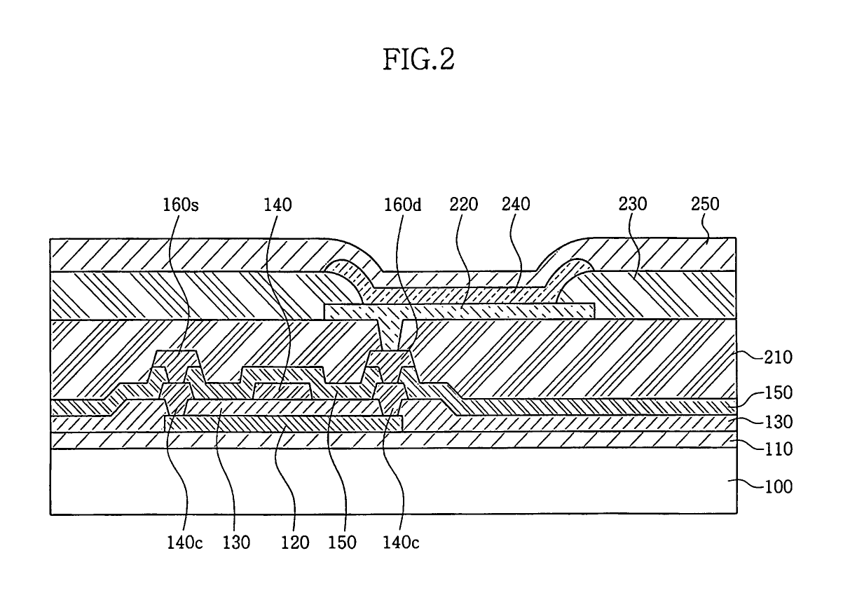

FIG. 2 illustrates a cross-sectional view of an OLED display device having a TFT according to a second example embodiment.

Referring to FIG. 2, a passivation layer 210 may be formed on the entire surface of the substrate 100 including the TFT according to the example embodiment described in FIG. 1D. The passivation layer 210 may be formed of an inorganic material, e.g., silicon oxide, silicon nitride, and silicate on glass, an organic material, e.g., polyimide, benzocyclobutene series resin and acrylate, or a combination thereof.

The passivation layer 210 may be etched to form a via hole exposing the source electrode 160s or drain electrode 160d. A first electrode 220 may be formed, and may be connected to one of the source and drain electrodes 160s and 160d through the via hole. The first electrode 220 may be an anode or a cathode. When the first electrode 220 is an anode, it may be formed of a transparent conductive layer, e.g., an ITO, IZO, or ITZO layer. When the first electrode 220 is a cathode, it may be formed of, e.g., magnesium (Mg), calcium (Ca), aluminum (Al), silver (Ag), barium (Ba), or an alloy thereof.

Subsequently, a pixel defining layer 230 may be formed on the first electrode 220. The pixel defining layer 230 may include an opening partially exposing a surface of the first electrode 220, and an organic layer 240 including an emission layer formed on the exposed portion of the first electrode 220. The organic layer 240 may further include one or more of a hole injection layer, a hole transport layer, a hole blocking layer, an electron blocking layer, an electrode injection layer, and an electron transport layer. Then, a second electrode 250 may be formed on the pixel defining layer 230 and on the organic layer 240. Accordingly, the OLED display device according to the second example embodiment may be completed.

Using a rapid annealing method that applies an electrical field to a conductive layer and generates Joule heat, it may be possible to rapidly anneal a selected material by transferring high heat. This is desirable, as the rapid annealing method may have a much higher heating rate than that of the conventional RTA method. However, such a rapid annealing method may introduce physical defects to the substrate from an arc generated during the Joule heating. Thus, according to embodiments, an electrode may be formed on the amorphous semiconductor layer before crystallization, such that occurrence of an arc caused by Joule heat during the crystallization operation may be prevented. Thus, defects can be reduced, and production yield may be improved. In addition, reduced contact resistance between source and drain electrodes and the semiconductor layer may be achieved.

Example embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A thin film transistor (TFT), comprising:
a buffer layer on a substrate;
a crystalline semiconductor pattern on the buffer layer;
a gate insulating layer on the crystalline semiconductor pattern, the gate insulating layer having a first source contact hole and a first drain contact hole therein;
a gate electrode on the gate insulating layer, the gate electrode being between the first source contact hole and the first drain contact hole;
an interlayer insulating layer covering the gate electrode, the interlayer insulating layer having a second source contact hole and a second drain contact hole therein;
a source electrode in the second source contact hole, the source electrode insulated from the gate electrode and electrically connected to the crystalline semiconductor pattern by a first metal pattern in the first source contact hole; and
a drain electrode in the second drain contact hole, the drain electrode insulated from the gate electrode and electrically connected to the crystalline semiconductor pattern by a second metal pattern in the first drain contact hole,
wherein the gate electrode, the first metal pattern in the first source contact hole, and the second metal pattern in the first drain contact hole are each made of a same material.

2. The TFT as claimed in claim 1, wherein:
the gate electrode is formed of a single layer or multiple layers, in which:
when the gate electrode is formed of a single layer, the single layer is aluminum or an aluminum alloy, and
when the gate electrode is formed of multiple layers, the multiple layers include a first layer of an aluminum alloy and a second layer of a chromium or molybdenum alloy.

3. The TFT as claimed in claim 2, wherein:
the first and second metal patterns are each formed of a single layer or multiple layers, in which:
when the first and second metal patterns are formed of a single layer, the single layer is aluminum or an aluminum alloy, and
when the first and second metal patterns are formed of multiple layers, the multiple layers include a first layer of an aluminum alloy and a second layer of a chromium or molybdenum alloy.

4. A method of fabricating a thin film transistor, the method comprising:
forming a buffer layer on a substrate;
forming an amorphous semiconductor layer on the buffer layer;
patterning the amorphous semiconductor layer to form an amorphous semiconductor pattern;
forming a gate insulating layer on the amorphous semiconductor pattern;
forming a first source contact hole and a first drain contact hole in the gate insulating layer;
forming a metal layer on the substrate, the metal layer covering the gate insulating layer, and being in the first source contact hole and the first drain contact hole so as to be electrically connected therethrough to the amorphous semiconductor pattern;
passing an electric current through the metal layer so as to convert the amorphous semiconductor pattern to a crystallized semiconductor pattern using heat generated by the electric current;
patterning the metal layer to form a gate electrode corresponding to the crystallized semiconductor pattern, a first metal pattern in the first source contact hole, and a second metal pattern in the first drain contact hole;
forming an interlayer insulating layer on the gate electrode, the first metal pattern, and the second metal pattern;
forming a second source contact hole and a second drain contact hole in the interlayer insulating layer; and
forming source and drain electrodes electrically connected to the first and second metal patterns, respectively, through the second source contact hole and the second drain contact hole.

5. The method as claimed in claim 4, wherein the electric current is generated by applying an electrical field of about 100 V/cm² to about 10,000 V/cm² to the metal layer.

6. The method as claimed in claim 4, wherein a same mask is used to form the first source contact hole, the first drain contact hole, the second source contact hole, and the second drain contact hole.

7. The method as claimed in claim 4, wherein:
the metal layer is formed of a single layer or multiple layers, in which:
when the metal layer is formed of a single layer, the single layer is aluminum or an aluminum alloy, and
when the metal layer is formed of multiple layers, the multiple layers include a first layer of an aluminum alloy and a second layer of a chromium or molybdenum alloy.

8. The method as claimed in claim 4, wherein the metal layer is formed to a thickness of about 50 nm to about 200 nm.

9. An organic light emitting diode (OLED) display device, comprising:
OLEDs configured to emit light; and
thin film transistors (TFTs) coupled to the OLEDs, each TFT including:
a buffer layer on a substrate;
a crystalline semiconductor pattern on the buffer layer;
a gate insulating layer on the crystalline semiconductor pattern, the gate insulating layer having a first source contact hole and a first drain contact hole therein;
a gate electrode on the gate insulating layer, the gate electrode being between the first source contact hole and the first drain contact hole;
an interlayer insulating layer covering the gate electrode, the interlayer insulating layer having a second source contact hole and a second drain contact hole therein;
a source electrode in the second source contact hole, the source electrode insulated from the gate electrode and electrically connected to the crystalline semiconductor pattern by a first metal pattern in the first source contact hole; and
a drain electrode in the second drain contact hole, the drain electrode insulated from the gate electrode and electrically connected to the crystalline semiconductor pattern by a second metal pattern in the first drain contact hole,
wherein the gate electrode, the first metal pattern in the first source contact hole, and the second metal pattern in the first drain contact hole are each made of a same material.

10. The OLED display device as claimed in claim 9, wherein:
the gate electrode is formed of a single layer or multiple layers, in which:
when the gate electrode is formed of a single layer, the single layer is aluminum or an aluminum alloy, and
when the gate electrode is formed of multiple layers, the multiple layers include a first layer of an aluminum alloy and a second layer of a chromium or molybdenum alloy.

11. The OLED display device as claimed in claim 10, wherein:
the first and second metal patterns are each formed of a single layer or multiple layers, in which:
when the first and second metal patterns are formed of a single layer, the single layer is aluminum or an aluminum alloy, and
when the first and second metal patterns are formed of multiple layers, the multiple layers include a first layer of an aluminum alloy and a second layer of a chromium or molybdenum alloy.
